(19) United States
(12) Patent Application Publication
(10) Pub. No.: US 2025/0366224 A1
(43) Pub. Date: Nov. 27, 2025

(54) NANOPILLAR STRUCTURE OF IMAGE SENSOR DEVICE AND METHOD OF FORMING

(71) Applicant: Applied Materials, Inc., Santa Clara, CA (US)

(72) Inventors: Qintao ZHANG, Mt Kisco, NY (US); Yen Lin LEOW, San Jose, CA (US); Manish HEMKAR, Singapore (SG); Zheng YUAN, Saratoga, CA (US)

(73) Assignee: Applied Materials, Inc., Santa Clara, CA (US)

(21) Appl. No.: 18/672,985

(22) Filed: May 23, 2024

(51) Int. Cl. H01L 27/146; G02B 1/00

(52) U.S. Cl. CPC H10F 39/024; G02B 1/002; H10F 39/8053; H10F 39/806; G02B 2207/101

(57) ABSTRACT

Disclosed herein are approaches for forming nanopillars of an image sensor. One method of forming an image sensor may include forming an etch stop layer atop a spacer layer, wherein the spacer layer is formed over a color filter, and forming a first optical material layer over the etch stop layer. The method may further include forming a plurality of pillars from the optical material layer, forming an opening through a first pillar of the plurality of pillars, the opening exposing the etch stop layer, and removing the etch stop layer by performing a wet etch through the opening, wherein the wet etch forms a cavity beneath the plurality of pillars. The method may further include forming a second optical material layer within the cavity.

### FIELD OF THE DISCLOSURE

The embodiments of the present disclosure relate to an image sensor and, in particular, to an image sensor having a nanopillar structure.

### BACKGROUND OF THE DISCLOSURE

Image sensors display images of various colors or detect the color of incident light by using a color filter. Color filters absorb unwanted wavelengths to filter and transmit only the desired color to the photodetector of the corresponding color channel, e.g., red, green, and blue. Although somewhat effective, this design is inefficient, capturing only a small fraction of light at the detector (e.g., less than 20-25% for a color filter array with a typical 2-by-2 pixel RGGB Bayer kernel), which makes low light imaging challenging and limits the practical size of image sensor pixels.

Recently, attempts have been made to use a meta lens to improve light utilization efficiency of image sensors. The meta lens separates colors of incident light by using diffraction or refraction characteristics of light that differ according to wavelengths, and adjusts the directionality of the incident light for each wavelength according to the refractive index and shape. To form high-aspect ratio pillars of the meta lens, a stack of trenched layers separated by one or more etch stop layers is often used. However, the etch stop layer(s) have suboptimal optical characteristics.

There remains a need in the art for a nano-pillar structure of an image sensor having improved optical performance in terms of refractive index and reduced processing complexity.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method of forming an image sensor may include forming an etch stop layer atop a spacer layer, wherein the spacer layer is formed over a color filter, and forming a first optical material layer over the etch stop layer. The method may further include forming a plurality of pillars from the optical material layer, forming an opening through a first pillar of the plurality of pillars, the opening exposing the etch stop layer, and removing the etch stop layer by performing a wet etch through the opening, wherein the wet etch forms a cavity beneath the plurality of pillars. The method may further include forming a second optical material layer within the cavity.

In another aspect, a method of forming a meta lens assembly may include forming an etch stop layer atop a spacer layer, wherein the spacer layer is formed over a color filter, and forming a first optical material layer over the etch stop layer. The method may further include forming a plurality of nanopillars from the optical material layer, forming an opening through a first nanopillar of the plurality of nanopillars, the opening exposing the etch stop layer, and removing the etch stop layer by performing a wet etch through the opening, wherein the wet etch forms a cavity between the spacer layer and the plurality of nanopillars. The method may further include forming a second optical material layer within the cavity and within the opening through the first nanopillar of the plurality of nanopillars.

In yet another aspect, an image sensor may include a spacer layer formed over a color filter, and a plurality of pillars formed over the spacer layer, wherein the plurality of pillars are formed from a first optical material layer. The image sensor may further include a second optical material between the plurality of pillars and the spacer layer, wherein the plurality of pillars are directly atop the second optical material layer, and a trench fill material formed between the plurality of pillars. The image sensor may further include a sealing layer over the plurality of pillars and over the trench fill material.

### BRIEF DESCRIPTION OF THE DRAWINGS

The accompanying drawings illustrate exemplary approaches of the disclosure, including the practical application of the principles thereof, as follows:

FIG. 1 illustrates a cross-sectional side view of an image sensor including a spacer layer and an etch stop layer formed over a color filter, according to embodiments of the present disclosure;

FIG. 2 illustrates a cross-sectional side view of the image sensor including a first optical material layer over the etch stop layer, according to embodiments of the present disclosure;

FIG. 3 illustrates a cross-sectional side view of the image sensor during patterning of a masking layer over the first optical material layer, according to embodiments of the present disclosure;

FIG. 4 illustrates a cross-sectional side view of the image sensor following formation of a plurality of trenches to form a plurality of pillars in the first optical material layer, according to embodiments of the present disclosure;

FIG. 5 illustrates a cross-sectional side view of the image sensor following formation of a trench fill material within the plurality of trenches, according to embodiments of the present disclosure;

FIG. 6 illustrates a cross-sectional side view of the image sensor following removal of a portion of the trench fill material, according to embodiments of the present disclosure;

FIG. 7 illustrates a cross-sectional side view of the image sensor during patterning of a second masking layer over the plurality of pillars and over the trench fill material, according to embodiments of the present disclosure;

FIG. 8 illustrates a cross-sectional side view of the image sensor after formation of one or more openings through the plurality of pillars, according to embodiments of the present disclosure;

FIG. 9 illustrates a cross-sectional side view of the image sensor after removal of the etch stop layer, according to embodiments of the present disclosure;

FIG. 10 illustrates a cross-sectional side view of the image sensor after formation of a second optical material layer, according to embodiments of the present disclosure;

FIG. 11 illustrates a cross-sectional side view of the image sensor after removal of the second masking layer and formation of a capping layer over the plurality of pillars and over the trench fill material, according to embodiments of the present disclosure; and

FIG. 12 illustrates a diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, disclosed herein are techniques to form a plurality of pillars in an optical medium of an image sensor. The plurality of pillars may be formed atop an etch stop later, which is later removed to form a cavity beneath the plurality of pillars. The cavity is then filled with a same or similar optical medium. By removing the etch stop layer from the finished device, the optical properties of the image sensor may be improved. Furthermore, by using this approach, a higher aspect ratio nanopillar structure may be achieved without increased processing complexity.

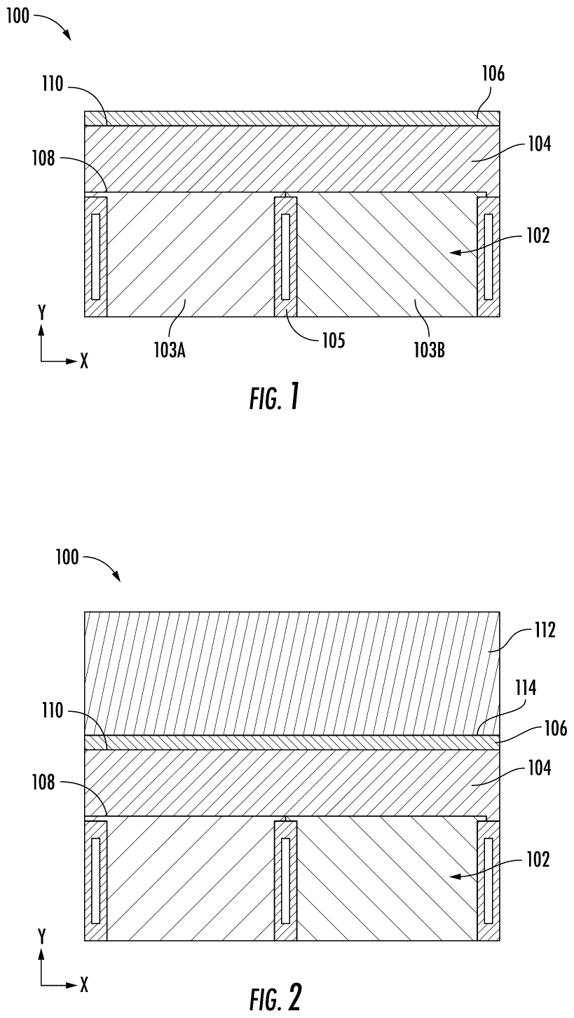

FIG. 1 illustrates an image sensor (hereinafter “sensor”) 100 at one stage of processing, according to embodiments of the present disclosure. In various embodiments, the sensor 100 may be a high-sensitivity complementary metal-oxide semiconductor (CMOS) image sensor (CIS), such as a meta lens image sensor, (also referred to as a meta lens assembly, meta optics, color splitting assembly, flat optics, nano-prism, or color routing assembly). Although the examples described herein operate over a spectrum including visible and near-infrared light, embodiments in accordance with the present disclosure can be configured for operation at wavelengths within virtually any electromagnetic spectral range, such as infrared, ultraviolet, multiple spectral ranges, and the like.

The sensor 100 may include a color filter 102, a spacer layer 104 formed atop the color filter 102, and an etch stop layer 106 formed atop the spacer layer 104. The color filter 102 may include a plurality of pixels 103A and 103B, which are separated by a grid of low-refractive-index (LRI) components 105. The color filter 102 may be arranged as a two-dimensional (2-D) array structure having a plurality of rows and a plurality of columns. Although not shown, the color filter 102 may be positioned over a plurality of photodiodes, which are formed in a substrate layer of the sensor 100. In some cases, the color filter 102 may not be present and, thus, the spacer layer 104 may be formed directly atop the plurality of photodiodes.

In some embodiments, the spacer layer 104 may be an oxide, e.g., silicon dioxide (SiO2) or silicon carbon nitride (SiCN), which is deposited over an upper surface 108 of the color filter 102 and then recessed (e.g., planarized) to a desired thickness. The etch stop layer 106, which may be a nitride, e.g., silicon nitride (SiN), is then deposited directly atop an upper surface 110 of the recessed spacer layer 104. The etch stop layer 106 may be formed to a non-limiting thickness of approximately 20 nm-50 nm.

As shown in FIG. 2, one or more first optical material layers 112 may be formed over the etch stop layer 106 and then recessed. Although non-limiting, the first optical material layer 112 may be a layer of amorphous titanium dioxide (TiO2), which is deposited directly atop an upper surface 114 of the etch stop layer 106. More specifically, the first optical material layer 112 may include TiO2 doped with aluminum (Al) or silicon (Si). In other embodiments, the first optical material layer 112 may include SiO₂, SiN3, Si3N4, ZnS, GaN, ZnSe, TiO2, or a combination thereof. The first optical material layer 112 may include materials having a same or higher refractive index (RI) than the material of the spacer layer 104. For example, the first optical material layer 112 may have a refractive index greater than two (2), while the spacer layer 104 may have a refractive index less than two (2).

As shown in FIG. 3, a first masking layer 116 may be formed over the first optical material layer 112. In some embodiments, the first masking layer 116 may be a photoresist, which is deposited directly atop an upper surface 120 of the first optical material layer 112 and then patterned using an electromagnetic radiation 122, for e.g., ultraviolet light (UV), deep ultraviolet light (DUV), extreme ultraviolet light (EUV), or X-ray. This exposure introduces a latent image or pattern on the photoresist with different areas of solubility, as desired.

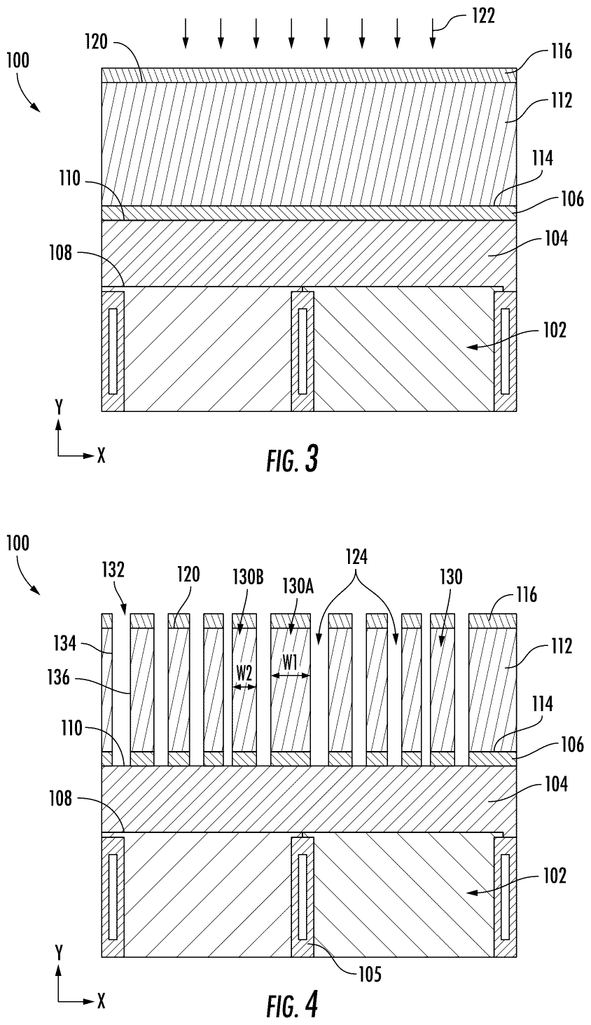

As shown in FIG. 4, a plurality of trenches 124 may then be formed in the first optical material layer 112 to produce a plurality of pillars 130. The trenches 124 may be formed through openings 132 of the first masking layer 116 formed as a result of the electromagnetic radiation 122. In some embodiments, the trenches 124 may be formed using a vertical etch process, which continues to the upper surface 110 of the spacer layer 104. For example, a first etchant may be used to generate a high etch selectivity of the first optical material layer 112 to the etch stop layer 106 (e.g., SiO2 of the first optical material layer 112 is etched faster than SiN of the etch stop layer 106). After the first etchant stops on the upper surface 114 of the etch stop layer 106, a second etchant may be used to generate a high etch selectivity of the etch stop layer 106 to the first optical material layer 112 (e.g., SiN of the etch stop layer 106 is etched faster than SiO2 of the first optical material layer 112).

Each of the plurality of pillars 130 may be defined by a first sidewall 134, a second sidewall 136, and the upper surface 114 of the etch stop layer 106. Although nonlimiting, the first sidewall 134 and the second sidewall 136 may be generally parallel to one another.

The plurality of pillars 130 may have a same or different horizontal width (e.g., in the x-direction), and the plurality of trenches 124 may have a same or different horizontal width. For example, in the embodiment shown, a first pillar 130A may have a first width, W1, and a second pillar 130B may have a second width, W2, wherein W1 is greater than W2. The size and width of each of pillar 130 may be a function of the desired routing of light having certain wavelengths. In some embodiments, the first pillar 130A may be generally aligned above the LRI component 105 of the color filter 102 so as to minimize interference with the light routing of the pillars 130 positioned above the first pixel 103A, and with the pillars 130 positioned above the second pixel 103B.

As shown in FIG. 5, the first masking layer 116 may be removed from the upper surface 120 of the first optical material layer 112, and a trench fill material 140 may be formed within each of the plurality of trenches 124. The trench fill material 140 may extend to the upper surface 110 of the spacer layer 104. In some embodiments, the first making layer 116 may be removed using a photoresist plasma ashing process in which oxygen and a fluorocarbon, such as CF₄ or C₂F₆, are supplied to the sensor 100 to strip the photoresist layers of the first masking layer 116.

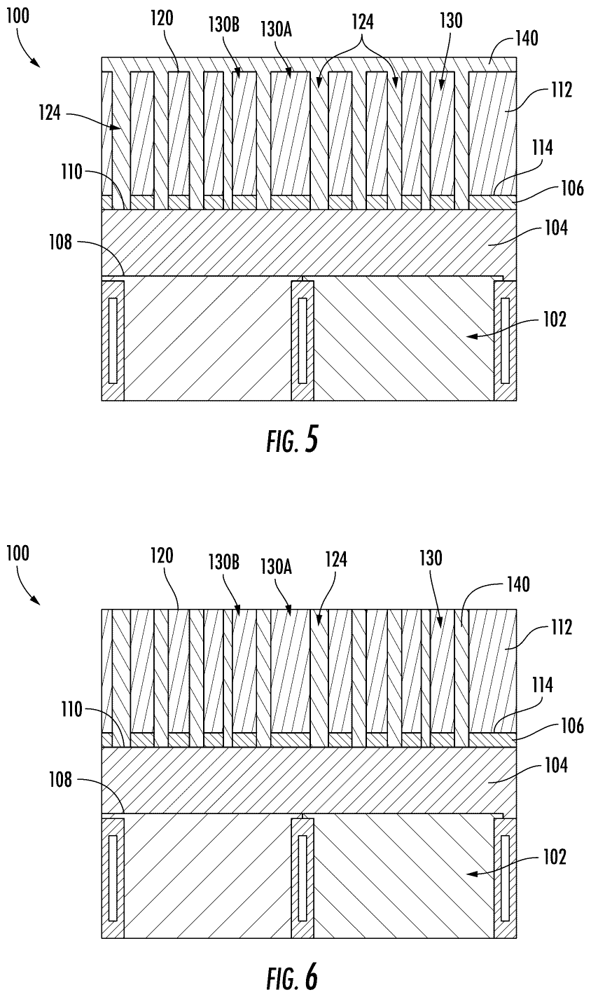

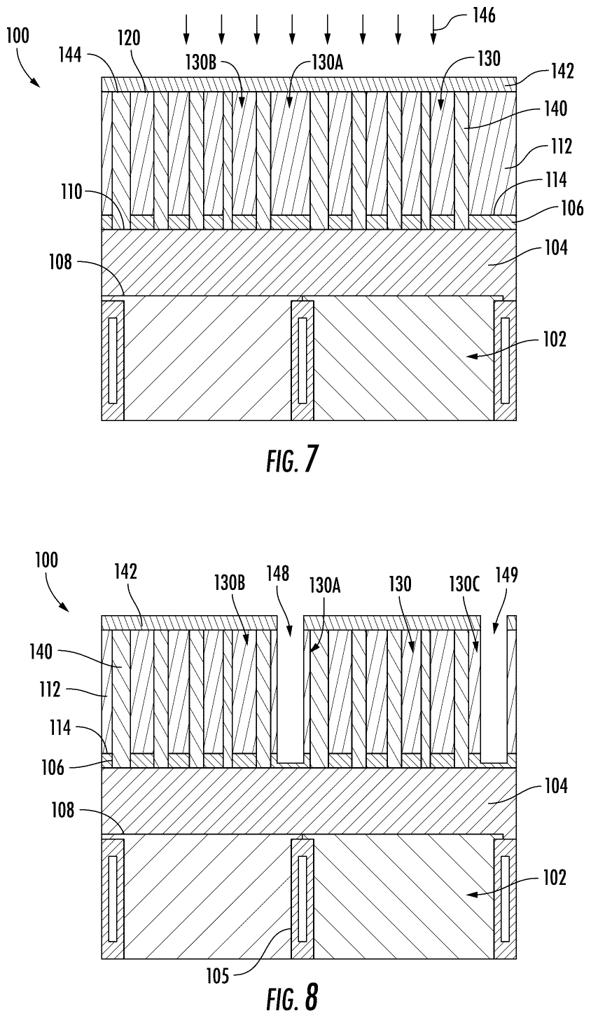

The trench fill material 140 may also be formed along the upper surface 120 of the first optical material layer 112 and then planarized or otherwise removed, resulting in the sensor 100 shown in FIG. 6. The trench fill material 140 may extend below the upper surface 114 of the etch stop layer 106. Although non-limiting, the trench fill material 140 may be a dielectric, such as silicon oxide, silicon nitride, silicon oxynitride, and others.

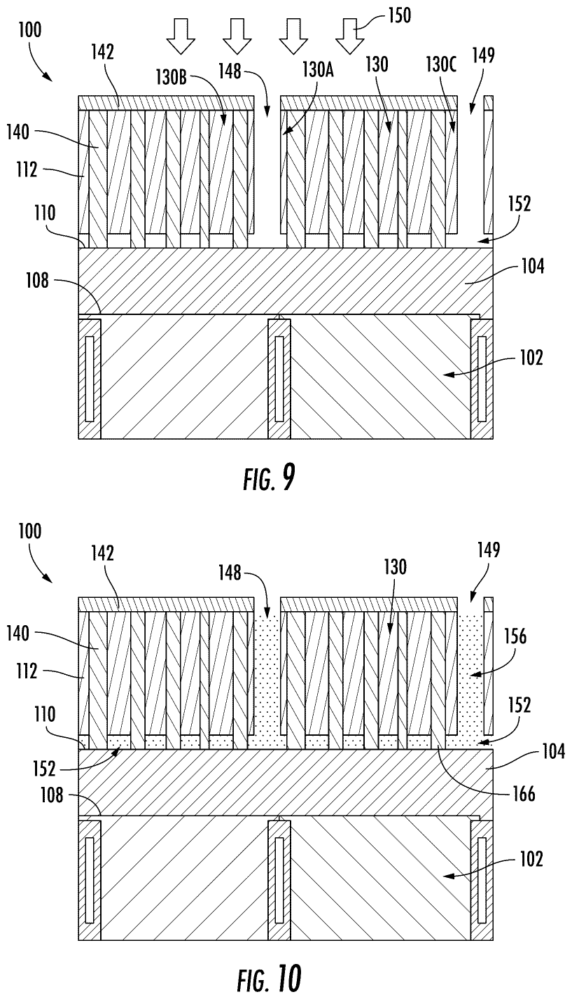

As shown in FIG. 7, a second masking layer 142 may be formed over the trench fill material 140 and over the plurality of pillars 130. In some embodiments, the second masking layer 142 may be a photoresist, which is deposited directly atop the upper surface 120 of the first optical material layer 112 and an upper surface 144 of the trench fill material 140. The second masking layer 142 is then patterned 146, as desired.

As shown in FIG. 8, one or more of the pillars 130 may be etched to form a first opening 148 and a second opening 149 therein. More specifically, the first opening 148 may be formed through the first pillar 130A, while the second opening 149 may be formed through a third pillar 130C. The first and second openings 148, 149 may generally be formed over the LRI components 105 of the color filter 102. Furthermore, the first and second openings 148, 149 may be formed partially into the etch stop layer 106, i.e., below a plane defined by the upper surface 114 of the etch stop layer 106. In some embodiments, a portion of the first optical material layer 112 may remain on either side of the first and second openings 148, 149. In other embodiments, the first pillar 130A and the third pillar 130C may be removed entirely, selective to a sidewall of an immediately adjacent section of the trench fill material 140. The number of pillar openings is not dispositive, however, as a greater or lesser number may be possible in alternative embodiments.

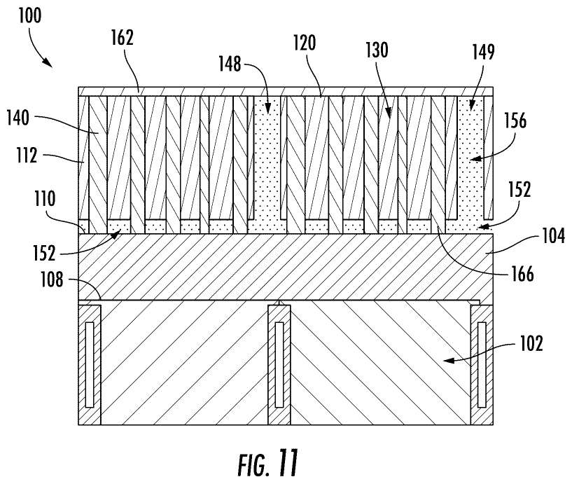

As shown in FIG. 9, the etch stop layer 106 may be removed by performing a wet etch 150 to form a cavity 152 beneath the plurality of pillars 130 and between the trench fill material 140. In general, the wet etch 150 is selective to the etch stop layer 106 and does not remove material from the pillars 130, the trench fill material 140, or the spacer layer 104. In some embodiments, the wet etch 150 may include delivering a solution into the first opening 148 and/or the second opening 149, wherein the solution may contain hydrofluoric acid (HF), phosphoric acid (H₃PO₄), one or more hydroxides (e.g., sodium hydroxide (NaOH), potassium hydroxide (KOH), lithium hydroxide (LiOH), ammonium hydroxide (NH₄OH)), or salts thereof. A dilute hydrofluoric acid (DHF) solution having a concentration from about 50:1 to about 1,000:1 (in water) can be used in some embodiments. However, the etching chemistry may vary in alternative embodiments, and can be selected based on the composition of the etch stop layer 106 to be removed.

As shown in FIG. 10, a second optical material layer 156 may be formed within the cavity 152. More specifically, the second optical material layer 156 may be deposited within the first and second openings 148, 149 via an atomic layer deposition (ALD) process until the second optical material layer 156 fills the cavity 152. As a result, the second optical material layer 156 is formed directly atop the upper surface 110 of the spacer layer 104, and in direct contact with an underside of the pillars 130. The second optical material layer 156 surrounds a lower portion 166 of the trench fill material 140 within the cavity 152. Advantageously, the cavity 152 and the first and second openings 148, 149 can be filled with a single ALD process, which reduces processing costs.

Although non-limiting, the second optical material layer 156 may be a layer of amorphous TiO2, doped or undoped. In other embodiments, the second optical material layer 156 may include SiO2, SiN3, Si3N4, ZnS, GaN, ZnSe, TiO2, or a combination thereof. The second optical material layer 156 may be the same material as the first optical material layer 112 (e.g., TiO2), and may therefore have a same or similar refractive index as well. In other embodiments, the first and second optical material layers 112, 156 may be different materials. In either case, the first and second optical material layers 112, 156 may include materials having a higher refractive index (e.g., R>2) than the material of the trench fill material 140 (e.g., R<1.7).

As shown in FIG. 11, the second masking layer 142 may be removed, e.g., using a photoresist plasma ashing process, selective to the upper surface 120 of the first optical material layer 112. A sealing layer 162 may then be formed atop the pillars 130 and the trench fill material 140. In some embodiments, the sealing layer 162 may be a nitride, e.g., SiN. However, other material may be used for the sealing layer 162 in alternative embodiments. The sealing layer 162 may have a lower refractive index than the first and second optical material layers 112, 156.

At this stage of processing, the sensor 100 shown in FIG. 11 may be CIS having the spacer layer 104 formed over the color filter 102, and the plurality of pillars 130 formed over the spacer layer 104, wherein the plurality of pillars 130 are formed from the first optical material layer 112. The CIS may further include the second optical material 156 between the plurality of pillars 130 and the spacer layer 104, wherein the plurality of pillars 130 are directly atop the second optical material layer 156 such that no etch stop layer is present between the plurality of pillars 130 and the spacer layer 104. In some embodiments the second optical material layer 156 is sandwiched between portions of the first optical material layer 112 of the first pillar 130A of the plurality of pillars 130. The CIS may further include the trench fill material 140 formed between the plurality of pillars 130, and the sealing layer 162 over the plurality of pillars 130 and the trench fill material 140. As shown, the second optical material layer 156 may surround the lower portion 166 of the trench fill material 140.

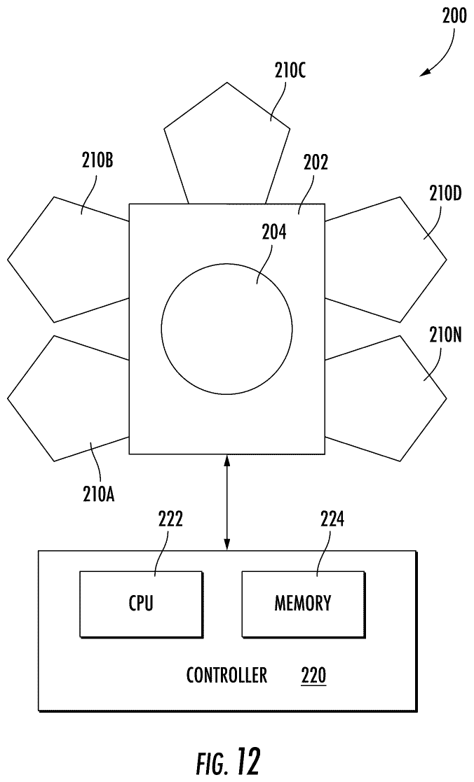

FIG. 12 shows a schematic of an example apparatus/system 200 according to implementations of the disclosure. In some implementations, the system 200 may be a cluster tool operable to perform processes necessary to form the sensor 100 described herein. Examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

As shown, the system 200 may include at least one central transfer station/chamber 202 and one or more robots 204 within the transfer station/chamber 202, wherein the robot 204 is operable to move a robot blade and a wafer to and from each of a plurality of processing chambers 210A-210N connected with, or positioned adjacent to, the transfer station/chamber 202. In some implementations, the processing chambers 210A-210N may support ion implantation, material deposition, material etching, thermal processing, and others. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some implementations, processing chamber 210A may be a deposition chamber operable to deposit one or more layers or features of the sensor 100. For example, the processing chamber 210A may include a material deposition tool operable to form the first optical material layer 112 over the etch stop layer 106, and to form the second optical material layer 156 within the first and second openings 148, 149 and within the cavity 152. The material deposition tool may be further operable to form the trench fill material 140 within each of the plurality of trenches 124. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition. The deposition chamber may further be an epitaxial growth deposition chamber.

In some implementations, processing chamber 210B may be an etch chamber operable to form one or more trenches through the body of the sensor 100. For example, the processing chamber 210B may include an ion etching tool operable to form the plurality of trenches 124 in the first optical material layers 112, and to form the first opening 148, the second opening 149, and the cavity 152. In some implementations, processing chamber 210B may be used for wet and/or dry etch processes. For example, a wet etch may be used to form the cavity 152 by removing the etch stop layer 106. In some implementations, the processing chamber 210B may be further operable to planarize one or more layers of the sensor 100, e.g., to partially remove the trench fill material 140 from over the pillars 130, and to recess the spacer layer 104 and the first optical material layer 112.

In some implementations, processing chamber 210C may be operable to perform an ion implant to the sensor 100, while processing chamber 210D may be operable to perform one or more thermal processes.

A system controller 220 is in communication with the robot 204, the transfer station/chamber 202, and the plurality of processing chambers 210A-210N. The system controller 220 can be any suitable component that can control the processing chambers 210A-210N and robot(s) 204, as well as the processes occurring within the process chambers 210A-210N. For example, the system controller 220 can be a computer including a central processor 222, memory 224, suitable circuits/logic/instructions, and storage.

Processes or instructions may generally be stored in the memory 224 of the system controller 220 as a software routine that, when executed by the processor 222, causes the processing chambers 210A-210N to perform processes of the present disclosure. The software routine may also be stored and/or executed by a second processor (not shown) that is remotely located from the hardware being controlled by the processor 222. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 222, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one implementation” of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of forming an image sensor, the method comprising:
forming an etch stop layer atop a spacer layer, wherein the spacer layer is formed over a color filter;
forming a first optical material layer over the etch stop layer;
forming a plurality of pillars from the optical material layer;
forming an opening through a first pillar of the plurality of pillars, the opening exposing the etch stop layer;
removing the etch stop layer by performing a wet etch through the opening, wherein the wet etch forms a cavity beneath the plurality of pillars; and
forming a second optical material layer within the cavity.

2. The method of claim 1, further comprising forming a sealing layer over the plurality of pillars.

3. The method of claim 1, further comprising planarizing the spacer layer before forming the etch stop layer.

4. The method of claim 1, further comprising:
patterning a masking layer over the first optical material layer; and
forming a plurality of trenches in the first optical material layer to form the plurality of pillars, wherein the plurality of trenches are formed through openings of the masking layer.

5. The method of claim 4, further comprising:
forming a trench fill material within the plurality of trenches; and
patterning a second masking layer over the trench fill material and over the plurality of pillars, wherein the opening formed through the first pillar of the plurality of pillars is formed through the second masking layer.

6. The method of claim 5, wherein the first optical material has a first refractive index, wherein the trench fill material has a second refractive index, and wherein the first refractive index is greater than the second refractive index.

7. The method of claim 1, wherein the first optical material layer and the second optical material layer are a same material, and wherein the second optical material is formed within the cavity using atomic layer deposition.

8. The method of claim 1, further comprising forming a second opening through a second pillar of the plurality of pillars, the second opening exposing the etch stop layer.

9. A method of forming a meta lens assembly, the method comprising:
forming an etch stop layer atop a spacer layer, wherein the spacer layer is formed over a color filter;
forming a first optical material layer over the etch stop layer;
etching the first optical material layer to form a plurality of nanopillars;
forming an opening through a first nanopillar of the plurality of nanopillars, the opening extending to the etch stop layer;
removing the etch stop layer by performing a wet etch through the opening, wherein the wet etch forms a cavity between the spacer layer and the plurality of nanopillars; and
forming a second optical material layer within the cavity and within the opening through the first nanopillar of the plurality of nanopillars.

10. The method of claim 9, further comprising:
patterning a masking layer over the first optical material layer; and
forming a plurality of trenches in the first optical material layer to form the plurality of nanopillars, wherein the plurality of trenches are formed through openings of the masking layer.

11. The method of claim 10, wherein the first optical material layer and the second optical material layer are a same material, and wherein the second optical material is formed within the cavity and within the opening of the first nanopillar using an atomic layer deposition.

12. The method of claim 11, further comprising:
forming a trench fill material within the plurality of trenches; and
patterning a second masking layer over the trench fill material and over the plurality of nanopillars, wherein the opening formed through the first nanopillar of the plurality of nanopillars is formed through the second masking layer.

13. The method of claim 12, wherein the cavity is further formed around the trench fill material.

14. The method of claim 11, further comprising:
removing the second masking layer from over the plurality of nanopillars; and
forming a sealing layer over the plurality of nanopillars and over the trench fill material after the second masking layer has been removed.

15. The method of claim 11, wherein the first optical material layer has a first refractive index, wherein the trench fill material has a second refractive index, and wherein the first refractive index is greater than the second refractive index.

16. The method of claim 9, further comprising forming a second opening through a second nanopillar of the plurality of nanopillars, the second opening exposing the etch stop layer.

17. An image sensor, comprising:
a spacer layer formed over a color filter;
a plurality of pillars formed over the spacer layer, wherein the plurality of pillars are formed from a first optical material layer;
a second optical material layer between the plurality of pillars and the spacer layer, wherein the plurality of pillars are directly atop the second optical material;
a trench fill material formed between each pillar of the plurality of pillars; and
a sealing layer over the plurality of pillars and over the trench fill material.

18. The image sensor of claim 17, wherein the first optical material layer and the second optical material layer are a same material, and wherein the second optical material layer is disposed within an opening of a first pillar of the plurality of pillars.

19. The image sensor of claim 18, wherein the color filter comprises a plurality of low refractive index structures, and wherein the second optical material layer within the opening of the first pillar of the plurality of pillars is vertically aligned over one of the plurality of low refractive index structures.

20. The image sensor of claim 17, wherein no etch stop layer is present between the plurality of pillars and the spacer layer.
